(19) United States
(12) Patent Application Publication
(10) Pub. No.: US 2026/0136534 A1
(43) Pub. Date: May 14, 2026

(54) SEMICONDUCTOR DEVICE STRUCTURE AND METHODS OF FORMING THE SAME

(71) Applicant: Winbond Electronics Corp., Taichung City (TW)

(72) Inventor: Ming-Chih HSU, Taichung City (TW)

(21) Appl. No.: 19/388,409

(22) Filed: Nov. 13, 2025

(30) Foreign Application Priority Data
Nov. 14, 2024 (TW) 113143791

(51) Int. Cl. H10B 12/00

(52) U.S. Cl. CPC H10B 12/315; H10B 12/09; H10B 12/50

(57) ABSTRACT

A semiconductor device with a capacitor structure and its formation method are provided. The semiconductor device with the capacitor structure includes a substrate, multiple inner support layers, an outer support structure, and multiple capacitor structures. The substrate has an array region and a peripheral region. The inner support layers are arranged in the array region on the substrate. A first support part of the outer support structure is arranged in the peripheral region on the substrate. A second support part of the outer support structure includes a connecting part that connects these inner support layers and a top extension part disposed on the first support layer. The thickness of the top extension part is different from the thickness of the inner support layer that is farthest from the substrate. Each capacitor structure passes through these inner support layers.

### CROSS REFERENCE TO RELATED APPLICATIONS

This Application claims priority of Taiwan Patent Application No. 113143791, filed on Nov. 14, 2024, the entirety of which is incorporated by reference herein.

### BACKGROUND OF THE INVENTION

### Field of the Invention

The present invention relates to semiconductor devices and methods of forming the same, and in particular, it relates to a semiconductor device having a capacitor structure with improved supporting strength and a method for forming the same.

### Description of the Related Art

Semiconductor technology has progressed in order to meet consumer demand for miniaturized electronic devices, and the manufacturing technology behind electronic devices has been striving towards miniaturization of component sizes, though many challenges remain. In manufacturing a conventional cylindrical capacitor structure, for example, a capacitor hole is typically formed within the alternating sacrificial oxide and nitride layers. The sacrificial oxide layers are subsequently removed entirely, leaving behind the nitride layers, which serve as a supporting structure for the cylindrical capacitor to be subsequently formed within the capacitor hole. As a result, the capacitance value of the cylindrical capacitor can be increased. However, as the size decreases and the aspect ratio of the capacitor hole increases, the strength of the conventional supporting structure needs to be improved. For example, the supporting structure at the edge of the array region is prone to breakage and collapse, which may in turn cause the cylindrical capacitor at the edge of the array region to collapse. In addition, the thickness of the dielectric layer on the sidewall of the cylindrical capacitor located at the edge of the array region may be significantly greater than the thickness of the dielectric layer on the sidewall of the cylindrical capacitor located in the center of the array region, resulting in the problem of uneven capacitance values. The above problems have an even greater impact on test keys formed using the same process, thereby reducing testing and production efficiency.

### BRIEF SUMMARY OF THE INVENTION

The capacitor structure and the method for forming the same disclosed in the present disclosure may address issues associated with conventional cylindrical capacitor structures, such as insufficient strength of the supporting structure, breakage of peripheral support structures, capacitor value non-uniformity, and/or reduced testing and production efficiency.

An embodiment of the present invention provides a semiconductor device having a capacitor structure, comprising: a substrate having an array region and a peripheral region outside the array region; a plurality of inner supporting layers disposed in the array region of the substrate and having a plurality of outer sidewalls adjacent to the peripheral region; an outer supporting structure, comprising: a first supporting portion disposed in the peripheral region of the substrate; and a second supporting portion, comprising: a connecting portion connecting the outer sidewalls of the inner supporting layers; and a top extension portion disposed on the first supporting portion, wherein a thickness of the top extension portion is different from a thickness of one among the inner supporting layers farthest from the substrate; and a plurality of capacitor structures located in the array region of the substrate, wherein each of the capacitor structures passes through the inner supporting layers and includes a bottom electrode, a top electrode, and a dielectric layer located between the bottom electrode and the top electrode.

Some embodiments of the present invention provides a method for forming a semiconductor device having a capacitor structure, comprising: forming a plurality of inner supporting layers in an array region on a substrate; forming an outer supporting structure, comprising: a first supporting portion formed in the peripheral region of the substrate; and a second supporting portion, comprising: a connecting portion connecting outer sidewalls of the inner supporting layers; and a top extension portion formed on the first supporting portion, wherein a thickness of the top extension portion is different from a thickness of one among the inner supporting layers farthest from the substrate; and forming a plurality of capacitor structures in the array region of the substrate, each of the capacitor structures passes through the inner supporting layers and includes a bottom electrode, a top electrode, and a dielectric layer located between the bottom electrode and the top electrode.

The embodiments in the present disclosure first define stacked islands comprising alternating sacrificial materials and supporting materials in the array region, and covers the outer sides of the stacked islands with a dielectric layer to reinforce the supporting materials. This approach ensures that the inner supporting layers maintain their integrity throughout the removal of the sacrificial material, ultimately enhancing the yield of the high aspect ratio capacitor structure.

### BRIEF DESCRIPTION OF THE DRAWINGS

The present invention can be more fully understood by reading the subsequent detailed description and examples with references made to the accompanying drawings, wherein:

FIGS. 1A, 2A, 3A, 4A, 5A, 6A, 7A, 8A, 9A, 10A, 11A, 12A, 13A, 14A, 15A, 16A, and 17A show partial top views of a semiconductor device having a capacitor structure at different intermediate manufacturing stages in an array region and a peripheral region according to some embodiments of the present disclosure;

FIGS. 1B, 2B, 3B, 4B, 5B, 6B, 7B, 8B, 9B, 10B, 11B, 12B, 13B, 14B, 15B, 16B, and 17B show cross-sectional views taken along line B-B′ shown in FIGS. 1A, 2A, 3A, 4A, 5A, 6A, 7A, 8A, 9A, 10A, 11A, 12A, 13A, 14A, 15A, 16A, and 17A, respectively; and

FIG. 18 shows a graph of a wafer at an intermediate manufacturing stage according to some embodiments of the present disclosure.

### DETAILED DESCRIPTION OF THE INVENTION

Embodiments of the present disclosure provide a semiconductor device having a capacitor structure and a method for forming the same. In some of the following embodiments, the semiconductor device may include, for example, a Dynamic Random Access Memory (DRAM), but the present invention is not limited thereto. The semiconductor device may also be any other semiconductor device having a capacitor structure, such as an electronic device including an integrated circuit of a silicon capacitor. Some embodiments of the present disclosure will be described in more details below with reference to the accompanying drawings.

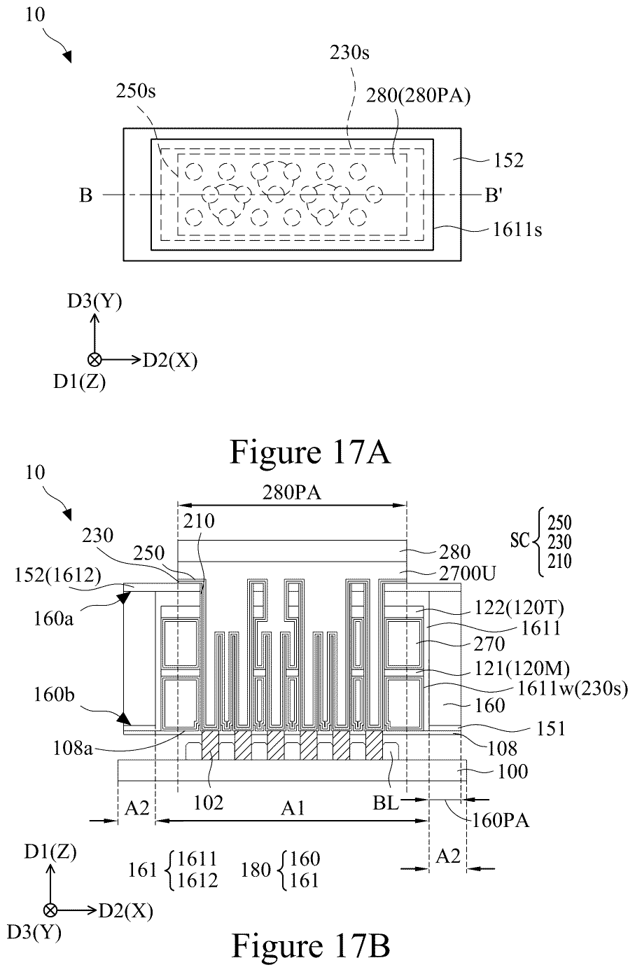

Referring to FIGS. 17A and 17B, a semiconductor device 10 having a capacitor structure SC of an embodiment of the present invention includes a substrate 100, a plurality of inner supporting layers 120M and 120T, an outer supporting structure 180, and a plurality of capacitor structures SC. The inner supporting layers 120M and 120T are disposed in the array region A1 of the substrate 100. The first supporting portion 160 of the outer supporting structure 180 is disposed in the peripheral region A2 of the substrate 100. The second supporting portion 161 of the outer supporting structure 180 includes a connecting portion 1611 connecting a plurality of outer sidewalls 121s and 122s (marked in FIG. 4B) of the inner supporting layers 120M and 120T, and a top extension portion 1612 disposed on the first supporting portion 160. Each capacitor structure SC passes through these inner supporting layers 120M and 120T.

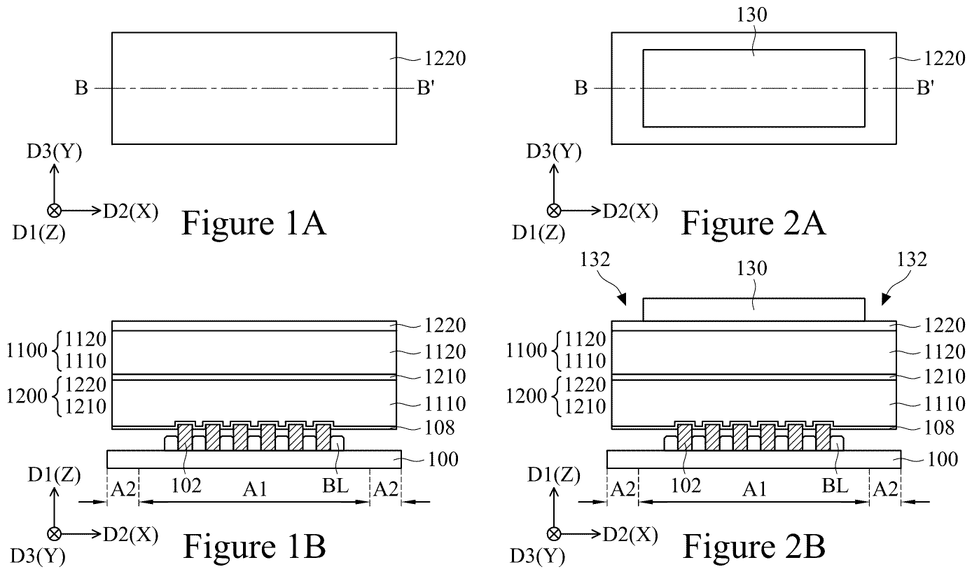

A method for forming a semiconductor device having a capacitor structure according to an embodiment of the present invention is described below. Referring to FIGS. 1A and 1B, a sacrificial material 1100 and a supporting material 1200 are alternately formed on a substrate 100. Specifically, the substrate 100 has an array region A1 and a peripheral region A2 outside the array region A1. The material of the substrate 100 may include a semiconductor material, such as silicon, gallium arsenide, gallium nitride, silicon germanium, or a combination thereof. In some embodiments, the substrate 100 may be a silicon-on-insulator (SOI) substrate. To simplify the figures, conventional features in the substrate 100, such as isolation structures for defining active regions and buried word lines, are omitted in these exemplary figures.

In some embodiments, a plurality of bit lines BL and a plurality of contact plugs 102 located in the array region A1 may be formed in an interlayer dielectric layer (not shown) over the substrate 100. In some embodiments, before alternately forming the sacrificial material 1100 and the supporting material 1200, a bottom isolation layer 108 may be formed on the interlayer dielectric layer (not shown) and cover the contact plug 102 and the bit line BL to protect the features under the bottom isolation layer 108 from damage or defects in the subsequent process of manufacturing the capacitor structure (such as dry or wet etching). The bottom isolation layer 108 may be located in the array region A1 and the peripheral region A2. The interlayer dielectric layer is, for example, one or more oxide layers. The bottom isolation layer 108 may be a nitride layer, such as a silicon nitride layer.

In the present embodiment, the sacrificial material 1100 includes a first sacrificial material layer 1110 and a second sacrificial material layer 1120, and the supporting material 1200 includes a first supporting material layer 1210 and a second supporting material layer 1220. The sacrificial material 1100 includes a dielectric material having an etching selectivity with the supporting material 1200, such as oxide. The supporting material 1200 includes a dielectric material that provides supporting strength, such as nitride. The present invention does not limit the number of layers of the sacrificial material 1100 and the supporting material 1200.

As shown in FIG. 1B, a first sacrificial material layer 1110, a first supporting material layer 1210, a second sacrificial material layer 1120, and a second supporting material layer 1220 are alternately formed, for example, along a first direction D1 (e.g., Z direction) on the substrate 100. The bit lines BL may be arranged at intervals in a second direction D2 (e.g., X direction), and the bit lines BL may extend along a third direction D3 (e.g., Y direction). The contact plug 102 may be formed between adjacent bit lines BL to electrically connect a capacitor structure to be formed subsequently with the substrate 100.

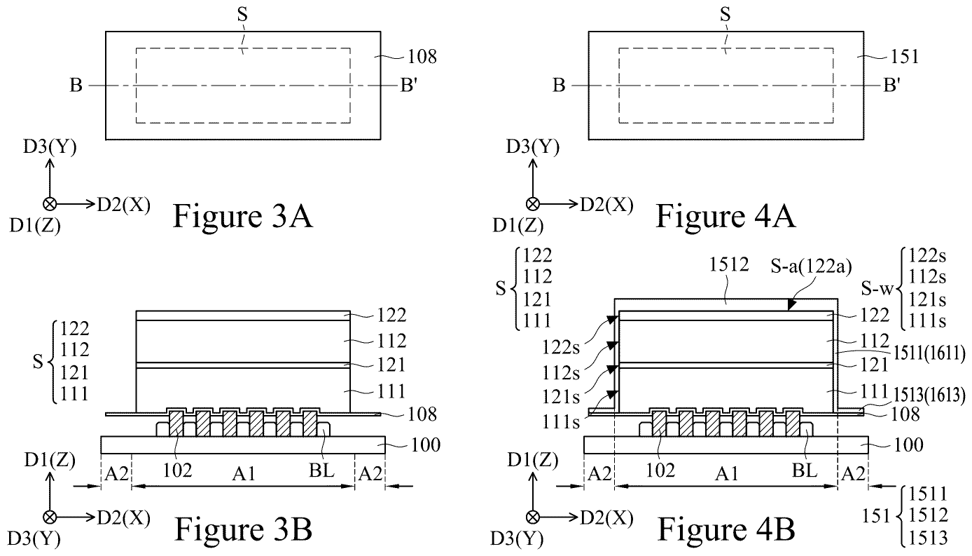

Referring to FIGS. 2A-2B to FIGS. 3A-3B, a stacked island S may be formed by patterning the sacrificial material 1100 and the supporting material 1200 such that the coverage of the stacked island S does not exceed the array region A1. As shown in FIGS. 2A and 2B, a mask 130 may be formed on the second supporting material layer 1220, and the coverage of the mask 130 does not exceed the array region A1, wherein the bit line BL and the contact plug 102 are also within the coverage of the mask 130.

Thereafter, referring to FIGS. 3A and 3B, the sacrificial material 1100 and the supporting material 1200 exposed by the opening 132 of the mask 130 are removed to form the stacked island S in the array region A1. The stacked island S may include a first sacrificial layer 111, a first supporting layer 121, a second sacrificial layer 112, and a second supporting layer 122, which are sequentially located on the substrate 100 from bottom to top along the first direction D1. Furthermore, the width of the stacked island S (e.g., in the second direction D2) does not exceed the width of the array region A1.

Note that during etching the sacrificial material 1100 and the supporting material 1200, the bottom isolation layer 108 may be substantially unaffected. In other words, the coverage of the stacked islands S is smaller than the coverage of the bottom isolation layer 108. Furthermore, although only a single array region A1 and a peripheral region A2 are shown in the figures, in some embodiments, a plurality of respective independent stacking islands S may be formed in array regions A1 on a wafer. After the stacked islands S are formed, the mask 130 may be removed by ashing or wet etching. An optional cleaning process may then be performed to remove residues.

Thereafter, referring to FIGS. 4A and 4B, a first dielectric layer 151 may be conformally and blanketly formed on the substrate 100 by a process such as physical vapor deposition (PVD), chemical vapor deposition (CVD), atomic layer deposition (ALD), and the like. In the context, when “blanketly formed” is mentioned, it means that the element is formed in both the array region A1 and the peripheral region A2.

In this exemplary embodiment, the outer sidewall 111s of the first sacrificial layer 111, the outer sidewall 121s of the first supporting layer 121, the outer sidewall 112s of the second sacrificial layer 112, and the outer sidewall 122s of the second supporting layer 122 constitute the outer sidewall S-w of the stacked island S. The top surface 122a of the second supporting layer 122 provides the top surface S-a of the stacked island S. The first portion 1511 of the first dielectric layer 151 may cover the outer sidewall S-w of the stacked island S to form the connecting portion 1611 of the second supporting portion 161, and the second portion 1512 of the first dielectric layer 151 may cover the top surface S-a of the stacked island S. In some embodiments, the third portion 1513 of the first dielectric layer 151 may cover the bottom isolation layer 108 in the peripheral region A2 to form a bottom extension portion 1613 of the second supporting portion 161.

Furthermore, the first dielectric layer 151 may include, for example, nitride, oxynitride, other suitable dielectric materials, or combinations thereof. In some embodiments, the first dielectric layer 151, the bottom isolation layer 108, the first supporting layer 121 and the second supporting layer 122 may have the same material, such as a silicon nitride layer, and the first dielectric layer 151 is in direct contact with the bottom isolation layer 108, the first supporting layer 121 and the second supporting layer 122 without having an interface.

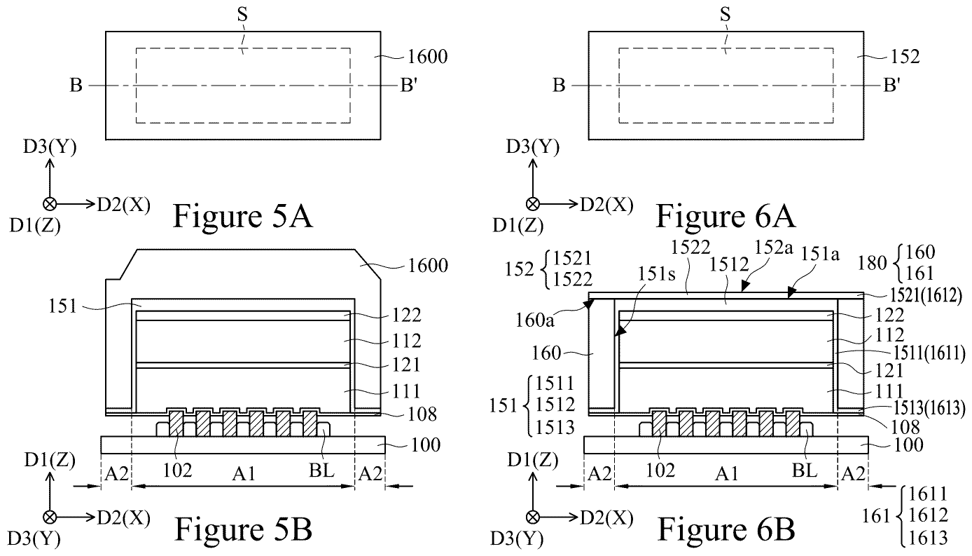

Thereafter, referring to FIGS. 5A and 5B, an insulating material layer 1600 may be blanketly formed on the first dielectric layer 151 by a deposition process such as PVD or CVD. The insulating material layer 1600 includes, for example, oxide, oxynitride, nitride, other suitable dielectric materials or combinations thereof. In some embodiments, the insulating material layer 1600 and the first dielectric layer 151 may include different materials. In this exemplary embodiment, the insulating material layer 1600 may be an oxide layer, and the first dielectric layer 151 may be a nitride layer.

Thereafter, referring to FIGS. 6A and 6B, according to some embodiments, the insulating material layer 1600 located in the array region A1 is removed by a planarization process such as a chemical mechanical polishing (CMP) process, an etching process, or a combination thereof, to expose the first dielectric layer 151. In this exemplary embodiment, the excess portion of the insulating material layer 1600 is removed by a CMP process until the top surface 151a of the second portion 1512 of the first dielectric layer 151 is exposed. The remaining portion of the insulating material layer 1600 forms the first supporting portion 160 located in the peripheral region A2. The first supporting portion 160 may surround the vertical sidewall 151s of the first dielectric layer 151. The top surface 160a of the first supporting portion 160 may be level with the top surface 151a of the second portion 1512 of the first dielectric layer 151.

Then, the second dielectric layer 152 may be blanketly formed on the first supporting portion 160 and the second portion 1512 of the first dielectric layer 151 by a process such as PVD, CVD, ALD, and the like. At this point, the manufacturing of the outer supporting structure 180 of the present embodiment may be completed. In the present embodiment, the first portion 1521 of the second dielectric layer 152 is formed on the first supporting portion 160 to form a top extension portion 1612 of the second supporting portion 161. The second portion 1522 of the second dielectric layer 152 is formed on the second portion 1512 of the first dielectric layer 151. The thickness of the second dielectric layer 152 may be different from the thickness of the first dielectric layer 151. The thickness of the second dielectric layer 152 is, for example, smaller than the thickness of the first dielectric layer 151.

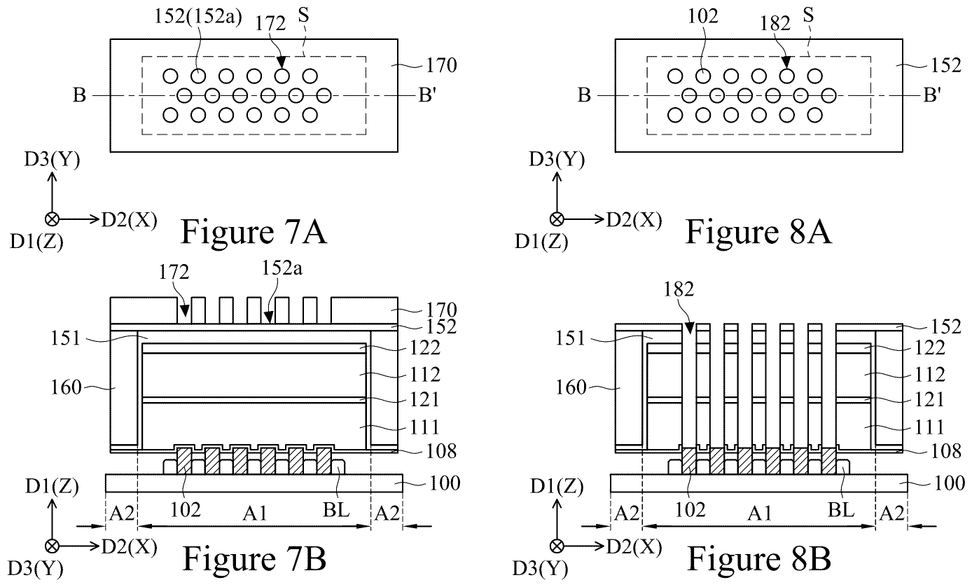

The second dielectric layer 152 may have a flat top surface 152a. The second dielectric layer 152 may include nitride, oxynitride, other suitable dielectric materials, or combinations thereof. The material of the second dielectric layer 152 may be the same as the material of the first dielectric layer 151, and for example, both are silicon nitride layers. The material of the second dielectric layer 152 may be different from the material of the first supporting portion 160. For example, the second dielectric layer 152 may be a silicon nitride layer and the first supporting portion 160 may be a silicon oxide layer. Referring to FIGS. 7A and 7B, a mask 170 may be formed on the second dielectric layer 152 through a patterning process. The mask 170 has a plurality of openings 172 located in the array region A1 to expose a portion of the top surface 152a of the second dielectric layer 152. In some embodiments, the openings 172 may correspond to the locations of the contact plugs 102.

Thereafter, referring to FIGS. 8A and 8B, a capacitor hole 182 penetrating the second dielectric layer 152, the first dielectric layer 151, the stacked island S, and the bottom insulating layer 108 may be formed through the opening 172 of the mask 170, for example, by performing an etching process. Each capacitor hole 182 extends, for example, in the first direction D1, and the capacitor holes 182 are spaced apart in the second direction D2. After forming the capacitor hole 182, the mask 170 is removed.

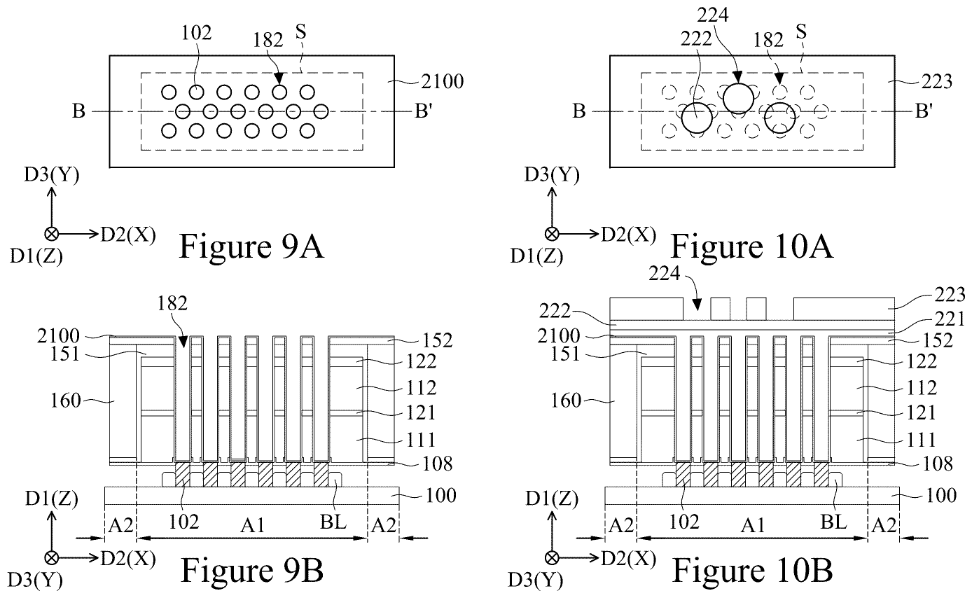

Thereafter, referring to FIGS. 9A and 9B, a bottom electrode material layer 2100 may be formed on the second dielectric layer 152 by CVD, ALD, PVD, or a combination thereof, and the bottom electrode material layer 2100 is deposited along the sidewalls and bottoms of the capacitor holes 182 and has a U-shaped cross-section in the capacitor holes 182. In some embodiments, the bottom electrode material layer 2100 in the capacitor hole 182 is in contact with and electrically connected to the contact plug 102. The bottom electrode material layer 2100 includes, for example, titanium, titanium nitride, tantalum, tantalum nitride, tungsten nitride, or other suitable conductive materials.

Thereafter, according to some embodiments, a process of removing the sacrificial material is performed, as shown in FIGS. 10A/10B-14A/14B.

Referring to FIGS. 10A and 10B, according to some embodiments, an oxide layer 221 is excessively deposited above the bottom electrode material layer 2100, and the oxide layer 221 fills the remaining space outside the bottom electrode material layer 2100 in the capacitor hole 182. Then, a mask material layer 222 is deposited on the oxide layer 221, and the top surface of the mask material layer 222 is a flat surface. Next, a mask 223 may be formed on the mask material layer 222 through a patterning process. The mask 223 has a plurality of openings 224 to expose a portion of the top surface of the mask material layer 222. The mask 223 is, for example, a patterned photoresist. In the present embodiment, the size of the opening 224 may cover portions of a plurality of adjacent capacitor holes 182.

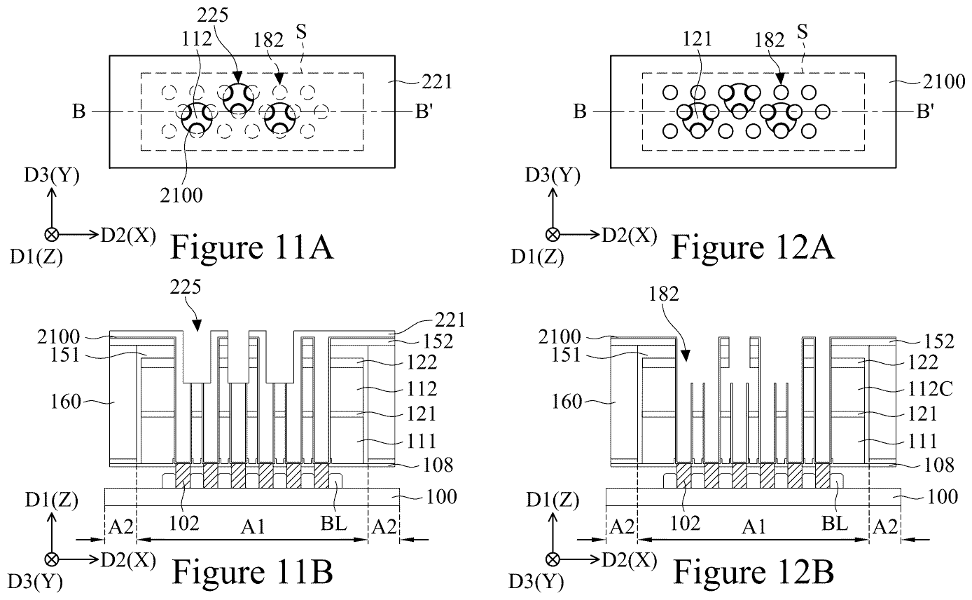

Thereafter, referring to FIGS. 11A and 11B, according to some embodiments, portions of the underlying material layers, including a portion of the oxide layer 221, a portion of the second dielectric layer 152, a portion of the first dielectric layer 151, a portion of the bottom electrode material layer 2100, and a portion of the second supporting layer 122, may be removed through the opening 224 of the mask 223 to form a plurality of recesses 225 exposing the second sacrificial layer 112. Thereafter, the mask 223 and the mask material layer 222 may be removed, and a cleaning process may be optionally performed to remove residues.

Thereafter, referring to FIGS. 12A and 12B, the second sacrificial layer 112 may be removed through the recess 225 to form an upper cavity 112C located in the array region A1. Furthermore, the remaining portion of the oxide layer 221 may be removed. In an exemplary embodiment where the second sacrificial layer 112 includes oxide, the oxide layer 221 and the second sacrificial layer 112 may be removed simultaneously.

According to the present embodiment, since the first supporting portion 160 is covered by the second dielectric layer 152 and the bottom electrode material layer 2100 as the second sacrificial layer 112 is removed, the first supporting portion 160 may be protected from damage. Therefore, after removing the second sacrificial layer 112, the second supporting layer 122 suspended on the upper cavity 112C in the array region A1 may be reinforced by the outer supporting structure 180, so that the second supporting layer 122 is less prone to breakage or collapse.

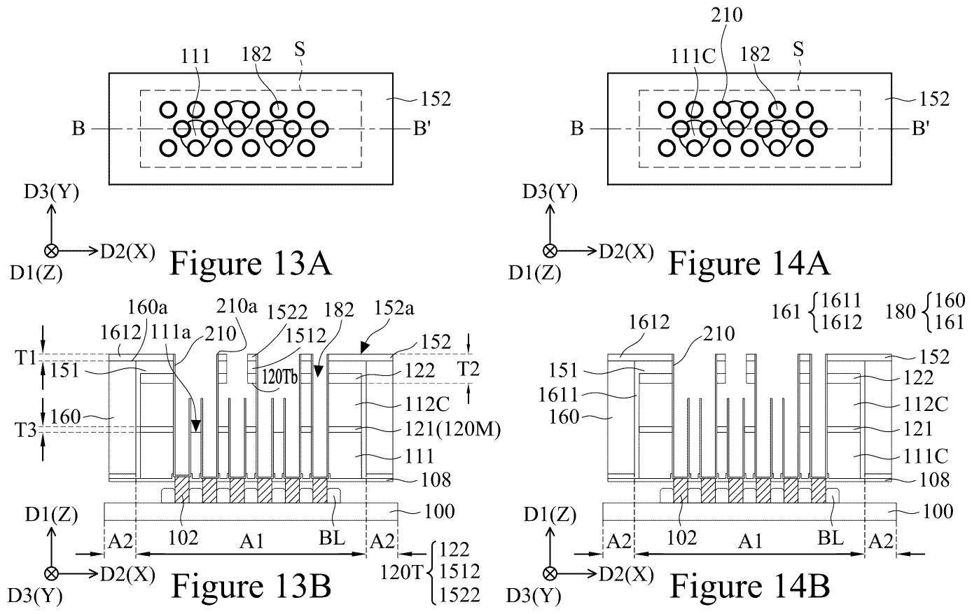

Referring to FIGS. 13A and 13B, according to some embodiments, an etch-back process may be performed to remove a portion of the bottom electrode material layer 2100 that exceeds the top surface 152a of the second dielectric layer 152, and the remaining portion of the bottom electrode material layer 2100 forms the bottom electrode 210. In the present embodiment, the second portion 1512 of the first dielectric layer 151, the second portion 1522 of the second dielectric layer 152, and the supporting material farthest from the substrate 100 (the second supporting layer 122 in the present embodiment) form an inner supporting layer 120T farthest from the substrate 100. The flat top surface of the second dielectric layer 152 may serve as the top surface of the top extension portion 1612 and of the top surface of the inner supporting layer 120T that is farthest from the substrate 100, and it may be level with the top surface 210a of the bottom electrode 210. The thickness T1 of the top extension portion 1612 may be different from a thickness T2 of the inner supporting layer 120T farthest from the substrate 100. In order to improve the supporting strength of the inner supporting layer 120T, the thickness T 1 of the top extension portion 1612 may be smaller than the thickness T2 of the inner supporting layer 120T farthest from the substrate 100. In order to improve the supporting strength of the outer supporting structure 180, the top surface 160a of the first supporting portion 160 may be higher than the bottom surface 120Tb of the inner supporting layer 120T.

Furthermore, according to some embodiments, after forming the bottom electrode 210, the exposed portion of the first supporting layer 121 in the upper cavity 112C is removed to expose a portion of the top surface 111a of the underlying first sacrificial layer 111 and form an inner supporting layer 120M.

Thereafter, referring to FIGS. 14A and 14B, the first sacrificial layer 111 may be removed through the exposed portion of the first sacrificial layer 111 by a suitable process (e.g., wet etching) to form a lower cavity 111C in the array region A1.

In the embodiment where the second dielectric layer 152, the first dielectric layer 151, and the supporting material 1200 contain nitride, and the sacrificial material 1100 contains oxide, an etching method having a higher removal rate for oxide may be selected to remove the first sacrificial layer 111 and the second sacrificial layer 112. Furthermore, since the first supporting portion 160 is covered by the second dielectric layer 152 as the first sacrificial layer 111 is removed, the first supporting portion 160 may be protected from damage. Therefore, after removing the first sacrificial layer 111, the second supporting layer 122 floating on the upper cavity 112C and the first supporting layer 121 floating on the lower cavity 111C in the array region A1 may be reinforced by the outer supporting structure 180, making these inner supporting layers 120M and 120T (marked in FIG. 13B) less likely to fracture or collapse. In this way, these inner supporting layers 120M and 120T can reliably support the bottom electrode 210, thereby improving the yield of the semiconductor device 10 and facilitating miniaturization.

In addition, for the capacitor structure SC with a high aspect ratio, the top of the capacitor structure SC is more likely to collapse than the bottom. Therefore, as shown in FIG. 13B, the thickness T2 of the inner supporting layer 120T farthest from the substrate 100 may be greater than the thickness T3 of the inner supporting layer 120M closest to the substrate 100, so as to increase the supporting strength of the inner supporting layer 120T farthest from the substrate 100, thereby improving the yield of the capacitor structure SC with a high aspect ratio.

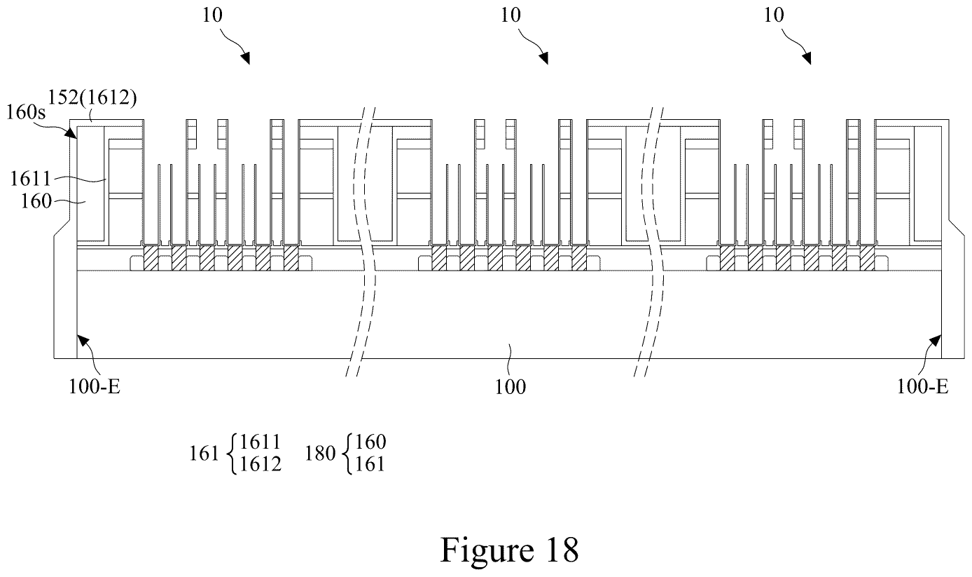

For semiconductor devices formed adjacent the edge of a wafer, they are particularly susceptible to damage during the manufacturing process, which may cause the structure therein to collapse. This risk is greater for miniaturized devices with capacitors. Please refer to FIG. 18, and according to some embodiments of the present invention, a wafer 1 includes a plurality of semiconductor devices 10 having a capacitor structure. For the semiconductor device 10 adjacent to a sidewall 100-E of the substrate 100 of the wafer 1, its second dielectric layer 152 (the top extension portion 1612 of the second supporting portion 161) covers the top surface and outer sidewall of the first supporting portion 160 and the sidewall 100-E of the substrate 100. As a result, the outer supporting structure 180 according to the present embodiment may improve the supporting strength of multiple internal supporting layers in the semiconductor device 10 adjacent to the sidewall 100-E of the substrate 100 of the wafer 1, thereby improving the yield of the semiconductor device 10 and facilitating miniaturization.

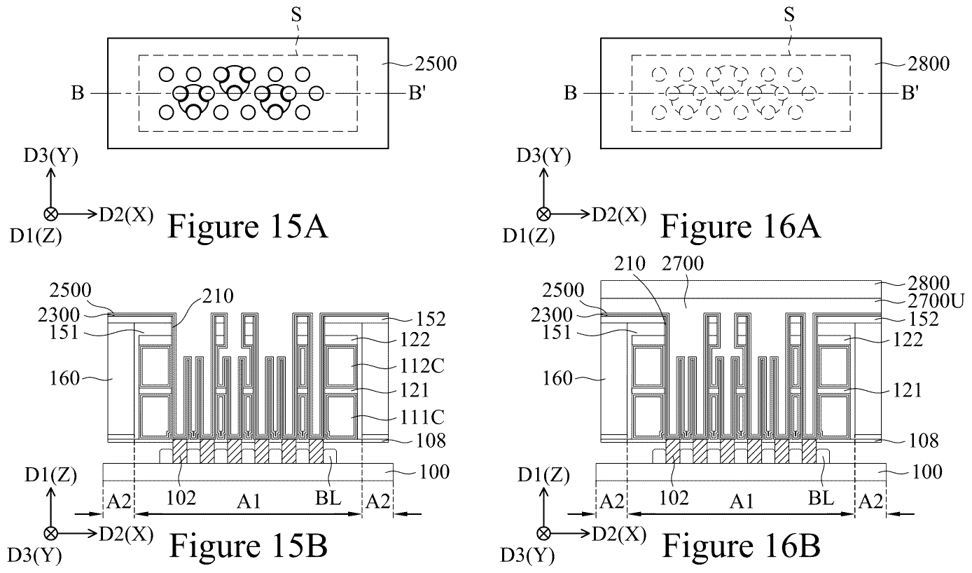

Referring to FIGS. 15A and 15B, according to some embodiments, after forming the upper cavity 112C, the lower cavity 111C, and the bottom electrode 210, a dielectric material layer 2300 is formed on the walls of the bottom electrode 210 and the lower cavity 111C, and the upper cavity 112C. For example, a dielectric material layer 2300 with a high dielectric constant (dielectric constant, for example, greater than or equal to 3.9) is conformally deposited on the inner and outer surfaces of the bottom electrode 210. The dielectric material layer 2300 is, for example, a two-layer structure of a silicon oxide layer/silicon nitride layer, but the invention is not limited thereto.

Then, a top electrode material layer 2500 is conformally formed on the dielectric material layer 2300. The dielectric material layer 2300 and the top electrode material layer 2500 may also be formed on the second dielectric layer 152 and extend in the array region A1 and the peripheral region A2. In some embodiments, the top electrode material layer 2500 includes titanium, titanium nitride, tantalum, tantalum nitride, tungsten nitride, or other suitable electrode materials. The top electrode material layer 2500 and the bottom electrode layer 210 may include the same material, such as titanium nitride layers, and may be formed by CVD, ALD, PVD or a combination thereof.

Thereafter, referring to FIGS. 16A and 16B, according to some embodiments, a conductive material layer 2700 is formed on the top electrode material layer 2500. The conductive material layer 2700 may be deposited in excess and fill the remaining space after the dielectric material layer 2300 and the top electrode material layer 2500 are formed in the lower cavity 111C and the upper cavity 112C. An upper portion 2700U of the conductive material layer 2700 is located above the top surface of the second dielectric layer 152. The conductive material layer 2700 includes a conductive material with good conductivity, such as boron-doped polysilicon, silicon germanium, high-concentration boron-doped silicon germanium and other silicon-containing conductive materials or other suitable conductive materials to reduce resistance value, and may be formed by CVD, ALD, PVD or a combination thereof. In some embodiments, the conductive material layer 2700 is a silicon

### Germanium Layer Deposited by Cvd.

Then, a metal material layer 2800 may be formed above the upper portion 2700U of the conductive material layer 2700. The metal material layer 2800 may include, for example (but not limited to), tungsten.

Thereafter, referring to FIGS. 17A and 17B, according to some embodiments, the portions of the metal material layer 2800, the conductive material layer 2700, the top electrode material layer 2500, and the dielectric material layer 2300 located within the peripheral region A2 are removed, and the remaining portions form a metal layer 280, a conductive filling layer 270, a top electrode 250, and a dielectric layer 230 in the array region A1, respectively. The top electrode 250, the dielectric layer 230, and the bottom electrode 210 form a capacitor structure SC. In the present embodiment, the top electrode 250 may cover the inner supporting layer 120T, and the outer sidewall 1611 s of the connecting portion 1611 may be farther away from the center of the array region A1 than the outer sidewall 250s of the top electrode 250. The dielectric layer 230 may cover the inner sidewall 1611w of the connecting portion 1611, and the outer sidewall 1611s of the connecting portion 1611 may be farther away from the center of the array region A1 than a surface 230s of the dielectric layer 230 closest to the peripheral region A2. The dielectric layer 230 may cover the inner supporting layer 120T, and the outer sidewall 1611 s of the connecting portion 1611 may be farther away from the center of the array region A1 than the surface 230s of the dielectric layer 230 closest to the peripheral region A2.

In addition, note that in the conventional method of manufacturing the capacitor structure, the conductive filling layer and the metal layer covering the capacitor structure may form a protruding tail structure on the peripheral region of the substrate, thereby adversely affecting the yield of the capacitor structure. In contrast, the capacitor structure SC according to an embodiment of the present disclosure does not have the tail structure. In the present embodiment, the capacitor structure SC may further include a metal layer 280 and a conductive filling layer 270. The metal layer 280 located in the array region A1 is formed on the top surface of the conductive filling layer 270. As shown in FIG. 17B, the vertical projection range 280PA of the metal layer 280 on the substrate 100 may not exceed the vertical projection range 160PA of the first supporting portion 160 on the substrate 100. From another perspective, the vertical projection range 280PA of the metal layer 280 on the substrate 100 does not overlap with the vertical projection range 160PA of the first supporting portion 160 on the substrate 100. The metal layer 280 may be used as an electrode connecting layer of the capacitor structure SC.

According to the semiconductor device with a capacitor structure and the method for forming the same of the present disclosure, since it does not have the traditional tail structure, the size of the array region A1 may be reduced, and the distance between the contact subsequently made in the peripheral region A2 and the array region A1 may be shortened, thereby reducing the overall size of the semiconductor device 10.

In the present embodiment, the bottom isolation layer 108 may include a first portion located between the dielectric layer 230 and the substrate 100, and a second portion located between the bottom extension portion and the substrate 100. To improve the strength of the outer supporting structure, the bottom surface 160b of the first supporting portion 160 may be higher than the top surface 108a of the first portion of the bottom isolation layer 108.

According to the method provided in the above embodiment, before forming the capacitor structure SC, the stacked island S in the array region A1 is first defined (FIGS. 2B, 3B), and two dielectric layer deposition processes (FIGS. 4B, 6B) are performed to cover the entire wafer to strengthen the inner supporting layer 120T in the array region A1 farthest from the substrate 100 and to form the outer supporting structure 180. Furthermore, when the sacrificial material in the array region A1 is removed, the outer supporting structure 180 is not affected. According to the semiconductor device 10 having the capacitor structure SC of the embodiment, the inner supporting layers 121 and 120T are reinforced by the outer supporting structure 180, so that the inner supporting layers 121 and 120T are not easily broken and can well support the capacitor structure SC with a high aspect ratio, thereby improving the yield of the semiconductor device 10.

Furthermore, during the wafer design stage, test keys are generally fabricated on the wafer scribe lines to evaluate whether the electrical performance of the manufactured elements meets the specified requirements in various aspects. In some embodiments, the semiconductor device 10 of the present embodiment may be used to manufacture a test key, wherein the top extension portion 1612 of the second supporting portion 161 may be used as a contact point of the test key for wafer testing to evaluate electrical properties of the element. According to the embodiment, the semiconductor device 10 of the present embodiment may be used in both the chip region and the test key of the wafer. Furthermore, due to the support of the first supporting portion 160 below, the top extension portion 1612 of the second supporting portion 161 is not easy to crack or break during the process (e.g., in the step of removing the sacrificial material), which also improves the yield of the WAT test key, thereby improving the test efficiency and accuracy.

In addition, according to the method of the present invention, since the substrate 100 in the peripheral area A2 is covered with the first dielectric layer 151, the second dielectric layer 152, and the first supporting portion 160 when the dielectric material layer 2300 is deposited (as shown in FIG. 14B), the precursor of the dielectric material layer 2300 will not enter the array region A1 from the peripheral region A2, and the thickness of the dielectric material layer 2300 may be better controlled. Regardless of whether the dielectric material layer 2300 is closer to or farther from the edge of the array region A1, it has the same and uniform thickness, thereby improving the operational performance of the capacitor structure SC and reducing power consumption.

Therefore, the semiconductor device having a capacitor structure and the method for forming the same of the present disclosure can improve yield of product, facilitate miniaturization and reduce power consumption, thereby achieving energy conservation and carbon reduction, reducing greenhouse gas emissions, and implementing a green process.

What is claimed is:

1. A semiconductor device having a capacitor structure, comprising:
a substrate having an array region and a peripheral region outside the array region;
a plurality of inner supporting layers disposed in the array region of the substrate and having a plurality of outer sidewalls adjacent to the peripheral region;
an outer supporting structure, comprising:
a first supporting portion disposed in the peripheral region of the substrate; and
a second supporting portion, comprising:
a connecting portion connecting the outer sidewalls of the inner supporting layers; and
a top extension portion disposed on the first supporting portion, wherein a thickness of the top extension portion is different from a thickness of one among the inner supporting layers farthest from the substrate; and
a plurality of capacitor structures located in the array region of the substrate, wherein each of the capacitor structures passes through the inner supporting layers and includes a bottom electrode, a top electrode, and a dielectric layer located between the bottom electrode and the top electrode.

2. The semiconductor device of claim 1, wherein a thickness of the top extension portion is smaller than a thickness of one among the inner supporting layers farthest from the substrate.

3. The semiconductor device of claim 1, wherein a thickness of one among the inner supporting layers farthest from the substrate is greater than a thickness of one of the inner supporting layers closest to the substrate.

4. The semiconductor device of claim 1, wherein the top extension portion is level with a top surface of one among the inner supporting layers farthest from the substrate and is level with a top surface of the bottom electrode.

5. The semiconductor device of claim 1, wherein a top surface of the first supporting portion is higher than a bottom surface of one of the inner supporting layers farthest from the substrate.

6. The semiconductor device of claim 1, wherein the top extension portion covers a top surface and an outer sidewall of the first supporting portion and a sidewall of the substrate.

7. The semiconductor device of claim 1, wherein the second supporting portion further comprising:
a bottom extension portion located between the substrate and the first supporting portion.

8. The semiconductor device of claim 7, further comprising:
a bottom isolation layer disposed on the substrate and comprising a first portion located between the dielectric layer and the substrate and a second portion located between the bottom extension portion and the substrate, wherein a bottom surface of the first supporting portion is higher than a top surface of the first portion of the bottom isolation layer.

9. The semiconductor device of claim 8, wherein materials of the second supporting portion and the first supporting portion are different, and materials of the bottom isolation layer, the inner supporting layers, and the second supporting portion are the same.

10. The semiconductor device of claim 1, wherein the top electrode covers one among the inner supporting layers farthest from the substrate, and an outer sidewall of the connecting portion is farther away from a center of the array region than an outer sidewall of the top electrode.

11. The semiconductor device of claim 1, wherein the dielectric layer covers an inner sidewall of the connecting portion, and an outer sidewall of the connecting portion is farther away from a center of the array region than a surface of the dielectric layer closest to the peripheral region.

12. The semiconductor device of claim 1, wherein the dielectric layer covers one among the inner supporting layers farthest from the substrate, and an outer sidewall of the connecting portion is farther away from a center of the array region than a surface of the dielectric layer closest to the peripheral region.

13. The semiconductor device of claim 7, further comprising:
a conductive filling layer formed on the top electrode and filling a space between the capacitor structures and a space surrounded by one among the inner supporting layers, the connecting portion, and the capacitor structures closest to the peripheral region; and
a metal layer formed on the conductive filling layer, and a range of vertical projection of the metal layer of the substrate does not exceed a range of vertical projection of an inner sidewall of the first supporting portion of the substrate.

14. The semiconductor device of claim 1, further comprising a plurality of contact plugs above the substrate, wherein the capacitor structure is located above the contact plugs and is electrically connected to the contact plugs.

15. A method for forming a semiconductor device having a capacitor structure, comprising:
forming a plurality of inner supporting layers in an array region on a substrate;
forming an outer supporting structure, comprising:
a first supporting portion formed in the peripheral region of the substrate; and
a second supporting portion, comprising:
a connecting portion connecting outer sidewalls of the inner supporting layers; and
a top extension portion formed on the first supporting portion, wherein a thickness of the top extension portion is different from a thickness of one among the inner supporting layers farthest from the substrate; and
forming a plurality of capacitor structures in the array region of the substrate, each of the capacitor structures passes through the inner supporting layers and includes a bottom electrode, a top electrode, and a dielectric layer located between the bottom electrode and the top electrode.

16. The method of claim 15, wherein a thickness of the top extension portion is smaller than a thickness of one among the inner supporting layers farthest from the substrate.

17. The method of claim 15, wherein the step of forming the inner supporting layers and the outer supporting structure comprises:
alternately forming a sacrificial material and a supporting material on the substrate;
patterning the sacrificial material and the supporting material to form a stacked island such that a coverage of the stacked island does not exceed beyond the array region;
forming a first dielectric layer, wherein a first portion of the first dielectric layer covers a sidewall of the stacked island to form the connecting portion of the second supporting portion, and a second portion of the first dielectric layer covers a top surface of the stacked island; and
forming a second dielectric layer on the first supporting portion and the second portion of the first dielectric layer, wherein the second dielectric layer formed on the first supporting portion forms the top extension portion of the second supporting portion, and the second portion of the first dielectric layer, the second dielectric layer formed on the second portion of the first dielectric layer, and the supporting material farthest from the substrate form one among the inner supporting layers farthest from the substrate.

18. The method of claim 17, further comprising:
before alternately forming the sacrificial material and the supporting material, forming a bottom isolation layer above the substrate in the array region and the peripheral region;
forming a third portion of the first dielectric layer covering the bottom isolation layer in the peripheral region to form a bottom extension portion of the second supporting portion; and
forming the first supporting portion on the third portion of the first dielectric layer.

19. The method of claim 17, wherein the step of forming the first supporting portion comprises:
forming an insulating material layer on the first dielectric layer in the array region and the peripheral region; and
removing the insulating material layer located in the array region so that a remaining portion of the insulating material layer forms the first supporting portion, and the top surface of the first supporting portion is level with the top surface of the second portion of the first dielectric layer.

20. The method of claim 15, wherein the dielectric layer covers an inner sidewall of the connecting portion, and an outer sidewall of the connecting portion is farther away from a center of the array region than a surface of the dielectric layer closest to the peripheral region.
